(19) United States
(12) Patent Application Publication
(10) Pub. No.: US 2020/0049755 A1
(43) Pub. Date: Feb. 13, 2020

(54) METHOD AND SYSTEM FOR DETECTING A FAULT IN A TRANSMISSION LINE FROM A PHASE MEASUREMENT

(71) Applicant: COMMISSARIAT A L'ENERGIE ATOMIQUE ET AUX ENERGIES ALTERNATIVES, PARIS (FR)

(72) Inventors: Esteban CABANILLAS, ORSAY (FR); Christophe LAYER, PARIS (FR)

(21) Appl. No.: 16/605,796

(22) PCT Filed: Apr. 12, 2018
(86) PCT No.: PCT/EP2018/059360

§ 371 Date: Oct. 16, 2019

(30) Foreign Application Priority Data
Apr. 19, 2017 (FR) 1753367

(51) Int. Cl. G01R 31/08; G01R 31/11

(52) U.S. Cl. CPC G01R 31/088; G01R 31/11

(57) ABSTRACT

A method for detecting a fault in a transmission line, includes the following steps: acquiring, at a point of the line, using a measurement device, a temporal measurement of a reference signal previously injected into the line using an injection device, reflected off a singularity of the line and propagated back to the point, converting the temporal measurement of the signal into the frequency domain, measuring the phase of at least one frequency component of the signal, subtracting a reference phase from each measured phase in order to obtain a corrected phase, determining the distance l_{d} between the point of the line and the singularity from at least one corrected phase.

The invention relates to the field of wire diagnostic systems based on the principle of reflectometry. One subject of the invention is a method for detecting faults in a transmission line, such as a cable, from a phase measurement of the reflectometry signal.

Cables are omnipresent in all electrical systems in order to supply power or to transmit information. These cables are subjected to the same constraints as the systems that they link, and may be subject to failures. It is therefore necessary to be able to analyze their state and to provide information about the detection of faults, but also their location and their type, so as to assist with maintenance. Conventional reflectometry methods enable this type of test.

Reflectometry methods use a principle close to that of radar: an electrical signal, the probe signal or reference signal, which is more often than not high-frequency or wideband, is injected at one or more locations of the cable to be tested. The signal propagates in the cable or the network and returns a portion of its power when it encounters an electrical discontinuity. An electrical discontinuity may be caused for example by a connection, by the end of the cable or by a fault or more generally by an interruption of the propagation conditions for the signal in the cable. It is caused more often than not by a fault that locally modifies the characteristic impedance of the cable by bringing about a discontinuity in its linear parameters.

Analyzing the signals returned to the point of injection makes it possible to deduce therefrom information about the presence and the location of these discontinuities, and therefore possible faults. An analysis in the time or frequency domain is usually performed. These methods are denoted using the acronyms TDR, stemming from the expression “time domain reflectometry”, and FDR, stemming from the expression “frequency domain reflectometry”.

The invention falls under the field of application of wire diagnostic methods, and is applicable to any type of electric cable, in particular power transmission cables or communication cables, in fixed or mobile installations. The cables in question may be coaxial, bifilar, in parallel rows, in twisted pairs or in another arrangement, provided that it is possible to inject a reflectometry signal into them at a point of the cable and to measure its reflection at the same point or at another point.

Accurate fault detection requires using a high-frequency signal so that the wavelength of the injected signal coincides with the physical dimensions of the faults in the cable. Now, analog-to-digital converters for injecting and measuring a high-frequency signal are expensive. Furthermore, the transmission channels corresponding to the various cable technologies targeted by reflectometry applications are more often than not highly selective in terms of frequency and therefore do not allow observation and a wideband diagnosis. Some frequency bands may be substantially attenuated or disrupted, thereby possibly making the signal measured by the reflectometry system unusable, or in any case making it more difficult to identify possible faults.

Moreover, conventional reflectometry methods are based on the principle of measuring an echo of the injected signal off a singularity of the analyzed cable. However, there are areas of the cable, called blind areas, at which an echo is not able to be measured. These areas depend on the wavelength of the signal, and therefore on its frequency, on the propagation speed of the signal, on the sampling frequency of the measured signal and on the distance between the point of injection of the signal and the point at which the singularity is located. If a fault occurs in a blind area, it is therefore not possible to detect the presence thereof using a conventional reflectometry method.

One known method for increasing the location resolution of a fault and for compensating the presence of blind areas without increasing the sampling frequency of the signal consists in performing multiple acquisitions of the signal propagated back in the cable by phase-shifting the sampling clock for each successive acquisition. This method provides relevant results insofar as the signal injected into the cable and measured in successive acquisitions is stationary throughout the entire duration of the acquisition. Furthermore, the accuracy of the measurements must comply with oversampling rules.

One major drawback of this method is that it requires a very lengthy acquisition and calculation time. This time is determined by the number of successive phase shifts and the phase shift times of the equipment used to generate the clock signals of the digital sampling systems. This delay may be unacceptable for detecting intermittent faults (for example a short circuit) whose duration is short. The calculations necessary to implement this method are also expensive, in particular for implementing phase shifts of the clock signal.

A wire diagnostic technique based on phase detection in the frequency domain is also known, as described in the document “You Chung Chung, C. Furse and J. Pruitt, “Application of phase detection frequency domain reflectometry for locating faults in an F-18 flight control harness,” in IEEE Transactions on Electromagnetic Compatibility, vol. 47, no. 2, pp. 327-334, May 2005”.

The method described in this document exhibits numerous drawbacks. It requires the implementation of complex analog radiofrequency “front-end” equipment requiring directional couplers, a voltage-controlled oscillator (VCO) and a radiofrequency mixer. The proposed method has a lengthy execution time since it requires frequency scanning over the entire useful frequency band, and signal acquisition for each frequency value of the scanning. Lastly, the location resolution of a fault is, as in the case of known time reflectometry methods, limited by the number of samples and the sampling frequency of the digital reflectometry signals that are used.

The invention proposes a method for detecting and locating an electrical fault in a transmission line that is based on analyzing the evolution of the phase of the frequency spectrum of the signal.

The invention notably has the advantage of allowing a fault location resolution that is not limited by the sampling frequency of the signal. It therefore makes it possible to locate a fault with better accuracy, without having to implement complex calculations and having a lengthy execution time. It makes it possible to detect and locate intermittent faults since, in contrast to conventional methods, it does not require a plurality of successive signal acquisitions to be performed. It also makes it possible to take into account any breaks in the frequency response of the cable to be analyzed without degrading the location accuracy of the fault.

The invention is applicable in particular to the detection of continuous or intermittent hard faults, such as a short circuit.

One subject of the invention is thus a method for detecting a fault in a transmission line, comprising the following steps:
Acquiring, at a point of the line, using a measurement device, a temporal measurement of a reference signal previously injected into the line using an injection device, reflected off a singularity of the line and propagated back to said point,
Converting the temporal measurement of the signal into the frequency domain,
Measuring the phase of at least one frequency component of the signal,
Subtracting a reference phase from each measured phase in order to obtain a corrected phase,
Determining the distance l_{d} between said point of the line and the singularity from at least one corrected phase.

According to one particular aspect of the invention, the distance l_{d} between said point of the line and the singularity is determined from a theoretical relationship expressing the phase as a function of the frequency, of the distance l_{d} and of the propagation speed of the signal in the transmission line.

According to one particular variant, the method according to the invention comprises the additional step of determining whether the identified singularity is a fault, at least from the determined distance l_{d} and from the length of the transmission line.

According to one particular aspect of the invention, the reference phase is a cumulative phase and measuring the phase of at least one frequency component comprises, for each frequency component, determining the phase modulo π and then determining the cumulative phase.

According to one particular variant of the invention, for each frequency component of the signal, the reference phase is equal to the phase of the same frequency component in the previously injected reference signal.

According to another particular variant of the invention, the reference phase is determined in a preliminary calibration phase comprising:
directly connecting the injection device to the measurement device,
injecting said reference signal,
temporally measuring the propagated reference signal,
frequency-converting the temporal measurement,
for each frequency component of the signal, measuring the phase of this component, the reference phase being equal to this measurement.

According to one particular variant, the method according to the invention comprises said preliminary calibration phase.

According to one particular variant, the method according to the invention furthermore comprises an interpolation step applied to a plurality of corrected phase values corresponding to a plurality of different frequency components.

According to one particular aspect of the invention, the temporal measurement of the signal is converted into the frequency domain by applying a Fourier transform to the signal.

According to one particular aspect of the invention, the reference signal is a multi-carrier signal, a frequency component of the signal being a frequency subcarrier of the multi-carrier signal.

According to one particular variant, the method according to the invention comprises a step of injecting the reference signal into the transmission line at an injection point.

Another subject of the invention is a system for detecting a fault in a transmission line comprising a measurement device able to acquire, at a point of the line, a temporal measurement of a reference signal previously injected into the line, reflected off a singularity of the line and propagated back to said point and:
a spectral conversion unit for converting the temporal measurement of the signal into the frequency domain,
a phase measurement device for measuring the phase of at least one frequency carrier of the signal,
a subtractor for subtracting a reference phase from each measured phase in order to obtain a corrected phase,
a calculation unit for determining the distance l_{d} between said point of the line and the singularity from at least one corrected phase.

According to one particular aspect of the invention, the calculation unit is configured so as to determine whether the identified singularity is a fault at least from the determined distance l_{d} and from the length of the transmission line.

According to one particular variant, the system according to the invention comprises a display interface for displaying information characteristic of the presence of a fault on the transmission line and/or of the location of the fault.

According to one particular variant, the method according to the invention comprises an injection device able to inject the reference signal into the transmission line.

Another subject of the invention is a computer program comprising instructions for executing the method for detecting a fault in a transmission line according to the invention when the program is executed by a processor and a recording medium able to be read by a processor and on which there is recorded a program comprising instructions for executing the method for detecting a fault in a transmission line according to the invention when the program is executed by a processor.

Other features and advantages of the present invention will become more clearly apparent upon reading the following description with reference to the appended drawings, in which:

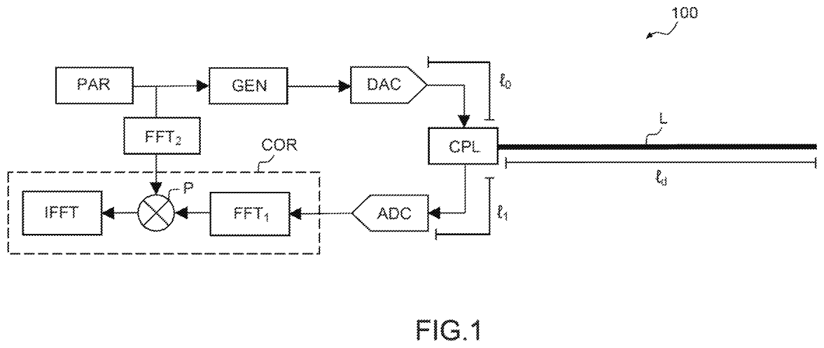

FIG. 1 shows a diagram of a system for locating a fault on a transmission line using a reflectometry method from the prior art,

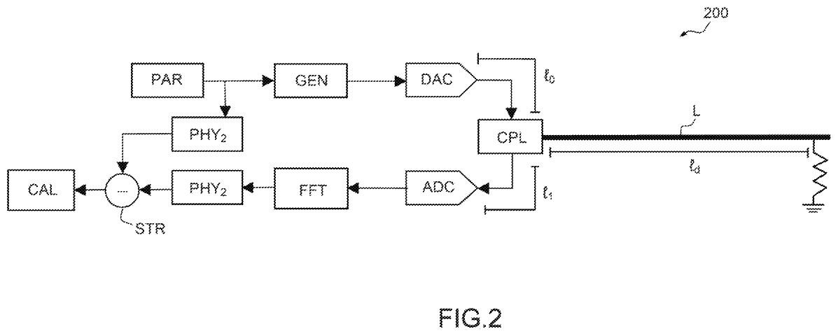

FIG. 2 shows a diagram of a system for locating a fault on a transmission line according to a first variant implementation of the invention,

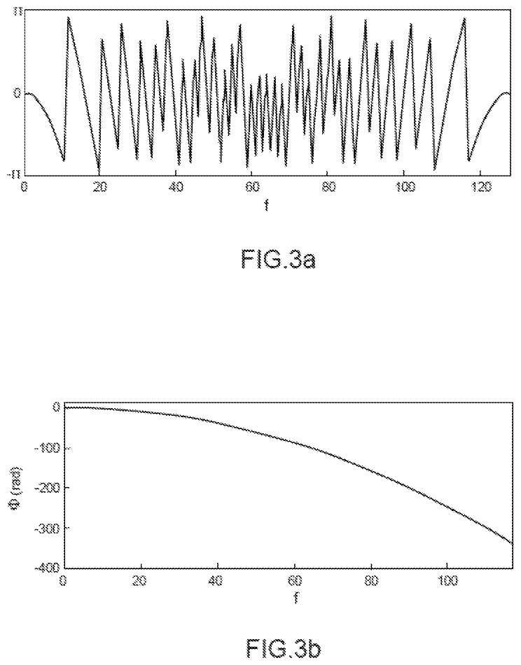

FIGS. 3a, 3b show a plurality of graphs illustrating the function of magnitude and of phase of a multi-carrier reflectometry signal,

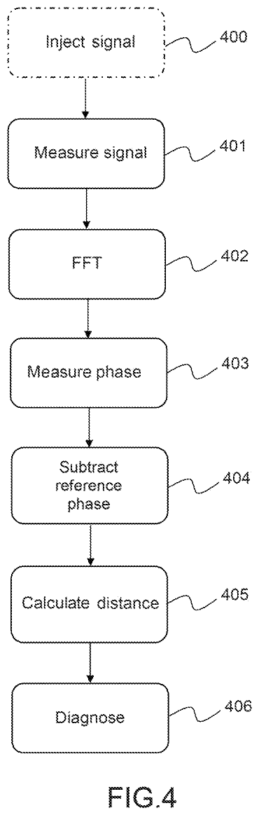

FIG. 4 shows a flowchart describing the steps for implementing a method for locating a fault on a transmission line according to the first variant implementation of the invention,

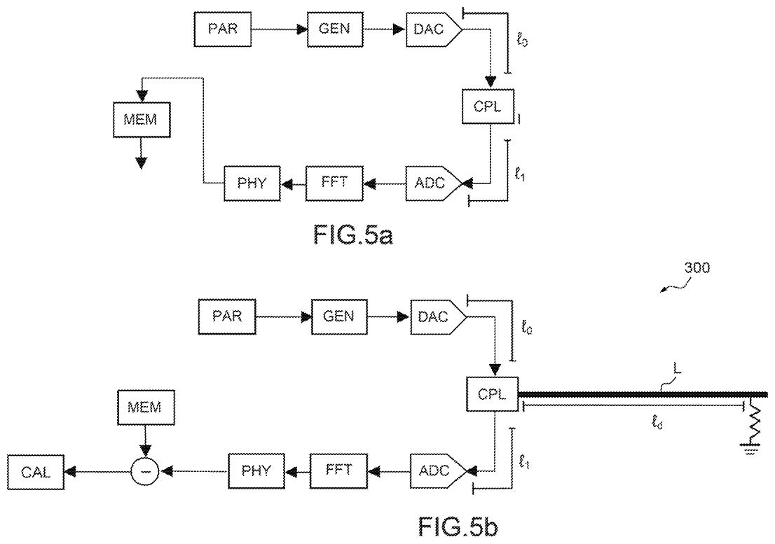

FIGS. 5a and 5b show two diagrams illustrating a second variant implementation of the fault location system according to the invention.

FIG. 1 shows a diagram of a system 100 for locating a fault in a transmission line L, such as a cable, using a conventional time reflectometry method from the prior art. Such a system primarily comprises a generator GEN for generating a reference signal based on parameters PAR defining the waveform of the signal. The generated digital reference signal is converted in an analog manner via a digital-to-analog converter DAC and is then injected at a point of the transmission line L by way of a directional coupler CPL. The signal propagates along the line and reflects off the singularities that it comprises. A singularity is an impedance discontinuity caused by the occurrence of an electrical fault on the line. In the absence of a fault on the line, the signal reflects off the end of the line if said end is not impedance-matched. If the end of the line is impedance-matched, that is to say that a resistive stop is attached to the end thereof, then there is no reflection of the signal since there is no impedance discontinuity. In the presence of a fault on the line, the signal reflects off the impedance discontinuity caused by the fault. The reflected signal is propagated back to a measurement point, which may be the same as the injection point or different. The back-propagated signal is measured via the directional coupler CPL and then converted digitally by an analog-to-digital converter ADC. A correlation COR is then made between the measured digital signal and a copy of the digital signal generated prior to injection in order to produce a time reflectogram corresponding to the intercorrelation between the two signals. To perform this intercorrelation, one possible implementation consists in performing a direct Fourier transform FFT₁ of the measured signal, a direct Fourier transform FFT₂ of the reference signal and then a product P of the two results, and then finally an indirect Fourier transform IFFT of the result of the product.

This implementation results from the following formula expressing the intercorrelation of two signals x(t) and x′(t):

c(t)=∫_{-∞}^{∞}x′(t+r)·x*(r)dr=TF⁻¹{TF{x′(t)}·TF{x*(t)}}

As is known in the field of time reflectometry-based diagnostic methods, the position d_{DF} of a fault on the cable L, in order words its distance to the point of injection of the signal, is able to be obtained directly from the measurement, on the calculated time reflectogram c(t), of the duration t_{DF} between the first amplitude peak shown on the reflectogram and the amplitude peak corresponding to the signature of the soft fault.

Various known methods may be contemplated to determine the position d_{DF}. A first method consists in applying the relationship linking distance and time: d_{DF}=V_{g}·t_{DF} where V_{g} is the propagation speed of the signal in the cable. Another possible method consists in applying a proportionality relationship of the type d_{DF}/t_{DF}=L_{c}/t₀, where L_{c} is the length of the cable and to is the duration, measured on the reflectogram, between the amplitude peak corresponding to the impedance discontinuity at the injection point and the amplitude peak corresponding to the reflection of the signal off the end of the cable.

The location resolution R of a fault for such a method, that is to say the accuracy obtained over the distance d_{DF}, is determined by the following relationship:

$$R = \frac{{v}_{g} c}{2 {f}_{adc}}$$

c is the speed of light and f_{adc} is the sampling frequency of the analog-to-digital converter.

One drawback of this method is that the resolution R is limited by the sampling frequency f_{adc}. The lower this is, the worse the resolution R will be. The resolution may be increased beyond the abovementioned limit by performing a plurality of successive acquisitions of the reflected signal with phase-shifted sampling times, that is to say times that are temporally shifted by a fraction of the sampling period. However, considering M successive acquisitions, the method is made at least M times slower, thereby impeding the detection of intermittent faults of very short duration. Furthermore, the overall processing time of the acquisitions of the signal also includes dead times linked to the phase-shift mechanism of the sampling dock, these dead times typically being of the order of a few tens of clock cycles.

The invention proposes to mitigate the drawbacks of the method described in FIG. 1 by proposing to utilize the phase of the measured signal to locate a fault.

The theoretical relationship that links the signal injected into the cable with the back-propagated and then measured signal in the frequency domain is as follows:

Y′(f)=Y(f)H(f)e^{-jφ(l,f)}=Y(f)e^{-jφ(l,f)}

Y(f) is the frequency spectrum of the signal injected into the cable, Y(f) is the frequency spectrum of the measured signal after propagation, H(f) is the amplitude response of the cable, which is assumed not to vary in terms of frequency, it is then written that H(f)=1. This assumption is made for cables that are not selective in terms of frequency. Moreover, the amplitude of the frequency response of the cable does not enter into the processing outlined hereafter, which is based only on utilizing the phase. For this reason, H(f)=1 is set arbitrarily in order to simplify the presentation of the invention.

Without departing from the scope of the invention, the amplitude response H(f) may be other than 1, without this modifying the steps of the method according to the invention.

It is therefore observed that the measured signal Y′(f) is phase-shifted with respect to the injected signal Y(f) by a phase shift that corresponds to the outward-return signal path in the cable as far as the reflection point.

This phase shift is equal to

$$ϕ ( l , f ) = 2 π f \frac{l}{{v}_{g}} ,$$

where l is the outward-return distance covered by the signal between the injection point and the measurement point, passing via the reflection point. The reflection point may correspond to the termination of the cable, in the absence of a fault and on a transmission line without a matched termination, and in this case l is equal to twice the length of the cable. If a hard fault is present on the cable during the test, the distance l is equal to twice the distance between the injection point (or measurement point) and the position of the fault on the cable. This is true in the scenario where the injection point and the measurement point are identical. In the opposite case, the relationship between l and the respective distances measured between the reflection point and the injection point or the measurement point is derived easily.

In the remainder of the description, it is assumed that the injection point and the measurement point are identical. If these two points are different, the relationships linking the phase of the signal with the position of a fault that are outlined hereinafter are easily able to be adapted by those skilled in the art using their basic mathematical knowledge.

It should also be noted that the context of the invention is that of detecting hard faults, that is to say for which the impedance discontinuity generated by the fault is such that the entire signal is reflected off this discontinuity. It is thus observed that utilizing the phase of the signal, which depends on the frequency f, may make it possible to locate a fault.

FIG. 2 shows a diagram of a fault detection system 200 according to a first variant implementation of the invention.

The system described in FIG. 2 has a plurality of elements in common with the system from the prior art described in FIG. 2: a digital reference signal generator GEN defined based on waveform parameters PAR, a digital-to-analog converter DAC, a directional coupler DCL for injecting the signal into a transmission line L and measuring the back-propagated signal, and an analog-to-digital converter ADC for digitizing the measured signal.

The system 200 also has a module for the spectral conversion of the signal, for example a module performing a discrete Fourier transform FFT, for converting the digital signal into the frequency domain.

The system 200 also has a first module PHY₁ for calculating the phase of the frequency signal at the output of the module FFT, a second module PHY₂ for calculating the phase of the reference signal in the frequency domain and a subtractor STR for subtracting the phase of the reference signal from the phase of the measured signal. Lastly, a calculation module CAL determines the existence and the possible position of a fault on the transmission line L from the corrected phase at the output of the subtractor STR.

It should be noted that the phase of the reference signal may be calculated directly from the parameters PAR of the reference signal or after a spectral conversion of the generated reference signal.

The phase calculation modules PHY₁ and/or PHY₂ may be implemented by way of calculating the arc-tangent function, for example implemented by way of a Cordic algorithm.

Without departing from the scope of the invention, the portion of the system 200 that relates to the generation and the injection of the signal may be separate from the portion of the system 200 that relates to the acquisition of a measurement of the reflected signal and the processing operations relating to the phase and distance calculations. In particular, two separate couplers CPL may be used, the first for injecting the reference signal at a first point of the line L and a second for measuring the back-propagated signal at a second point of the line L.

Advantageously, the reference signal that is used is a multi-carrier signal, for example an OFDM (orthogonal frequency division multiplexing) or MCTDR (multi-carrier time domain reflectometry) or OMTDR (orthogonal multi-tone time domain reflectometry) signal that comprises a plurality of frequency subcarriers fₙ.

However, the invention may also operate with a single-carrier reference signal, as will be explained in more detail hereafter.

As explained above, the phase of the measured signal is given by the following relationship:

$${ϕ}_{d} ( {l}_{d} , {f}_{n} ) = {ϕ}_{ref} ( {f}_{n} ) + 2 π {f}_{n} \frac{2 {l}_{d}}{{v}_{g}} \qquad ( 1 )$$

fₙ is the frequency of the subcarrier for which the phase is measured,
l_{d} is the distance between the measurement point and the reflection point of the signal (possibly corresponding to a fault),
φ_{ref}(fₙ) is a reference phase, which depends on the frequency and which corresponds to the phase of the reference signal, in other words the phase measured at the output of the module PHY₂.

From relationship (1), it is deduced that the phase obtained after subtracting STR the reference phase from the phase of the measured signal is expressed as a function of the position of the possible fault:

$$d {ϕ}_{d} ( {l}_{d} , {f}_{n} ) = {ϕ}_{d} ( {l}_{d} , {f}_{n} ) - {ϕ}_{ref} ( {f}_{n} ) = 2 π {f}_{n} \frac{2 {l}_{d}}{{v}_{g}} \qquad ( 2 )$$

The calculation module CAL then determines the value of l_{d}, for one or more frequencies fₙ:

$${l}_{d} = \frac{d {ϕ}_{d} ( {l}_{d} , {f}_{n} ) \cdot {v}_{g}}{4 π {f}_{n}} \qquad ( 3 )$$

In the case of a multi-carrier signal, the phase calculation module PHY₁ (and possibly the phase calculation module PHY₂) performs one phase calculation per subcarrier of the signal.

One advantage of using a multi-carrier signal is that it makes it possible to remove possible phase ambiguities. Specifically, calculating a phase using the arc-tangent function gives a result modulo π, that is to say between −π and +π. Now, applying relationships (1) and (2) assumes having a real phase value, in other words shown cumulatively on the frequencies.

FIGS. 3a and 3b illustrate this phenomenon on two graphs showing the evolution of the phase of a multi-carrier signal as a function of frequencies.

FIG. 3a shows the phase measured for each carrier by way of calculating the arc-tangent function. This phase is expressed modulo u.

FIG. 3b shows the same cumulative phase on the carriers, in other words, the phase value for the frequency of index n is equal to the sum of the phases of the frequencies for the indices varying within the interval [0; n]. It is observed in FIG. 3b that the evolution of the cumulative phase is continuous in terms of frequency. The relationships linking the phase with a distance value between two points of the line L are based on a phase shown cumulatively.

Thus, according to one particular aspect of the invention, if the modules PHY₁, PHY₂ implement a phase calculation by way of the arc-tangent function, an additional calculation of the cumulative phase on the frequencies is performed by way of the following relationship:

$${ϕ}_{c} ( {l}_{d} , {f}_{n} ) = {\sum }_{i = 0}^{n} ϕ ( {l}_{d} , {f}_{i} )$$

Relationship (3) may be applied for one subcarrier fₙ or a plurality of subcarriers. In the second case, a plurality of values of the distance l_{d} are obtained, which may be averaged in order to reduce the measurement noise and improve the location accuracy.

Depending on the type of cable to be tested, some frequency bands may be attenuated or disturbed or else reserved for a service. In this case, the multi-carrier reference signal may accordingly be generated by eliminating certain subcarriers corresponding to the frequency bands that are forbidden or likely to be disturbed.

In such a case in particular, the various cumulative phase values may be interpolated in order to increase the number of points, with the knowledge that the evolution of the phase as a function of the frequency is continuous.

The invention is also compatible with a single-carrier signal. However, in such a case, a single phase value is measured, and it is not possible to remove possible ambiguity modulo π with regard to this value. In this case, the maximum possible distance l_{d} between the injection point and the point of occurrence of the fault is linked to the carrier frequency f₀ of the signal by the following relationship:

$$\frac{{f}_{0} * 2 * {l}_{d}}{{v}_{g}} < 1$$

If this inequality is not complied with, this means that the phase shift induced by the reflection of the signal off a reflection point situated at the distance l_{d} is greater than 2π and is therefore not able to be interpreted correctly.

FIG. 4 summarizes the steps for implementing the method for detecting a fault according to the first variant implementation of the invention.

In a first step 400, a reference signal is injected at an injection point of a transmission line L. This step is not considered from the perspective just of the method executed by a system 200 that does not comprise the portion relating to the generation and to the injection of the signal, which portion is implemented in a separate system.

In another step 401, the signal propagated back in the line L is measured at a measurement point. The signal is then converted 402 into the frequency domain. The phase of at least one frequency carrier of the signal is then measured 403, preferably the cumulative phase in particular in the case of a multi-carrier signal.

A reference phase corresponding to the phase of the same frequency carrier for the generated reference signal is then subtracted 404 from the measured phase for each frequency carrier. Next, the distance between the measurement point and a reflection point of the signal, corresponding to a possible fault, is determined 405 from the result of the subtraction 404. In another step 406, a diagnosis is produced with regard to the presence of a fault and to its position at the distance determined in step 405. To ascertain whether the reflection point corresponds to a singularity associated with a fault, the calculated distance is compared with the length of the cable in order to identify whether the reflection point corresponds to the termination of the cable, in which case this means that there is not a fault. In the opposite case, this comparison gives the information about the existence of a fault, and the value of the distance determined in step 405 gives the location of the fault.

The result of the diagnosis may be provided to a user through a display interface. The displayed result may comprise an indication of the presence of a fault on the line and/or an indication regarding the position of the fault on the line, determined from the distance calculated in step 405.

FIGS. 5a and 5b show a diagram of a fault detection system 300 according to a second variant implementation of the invention.

According to this second variant, a calibration phase, illustrated in FIG. 5a, is performed before the fault detection phase illustrated in FIG. 5b. The aim of the calibration phase is to measure more accurately the reference phase that is subtracted from the phase of the signal in step 404 of the method.

Referring again to relationship (1), the reference phase is in reality equal to:

$${ϕ}_{ref} ( {f}_{n} ) = {ϕ}_{0} ( {f}_{n} ) + 2 π {f}_{n} \frac{{l}_{0} + {l}_{1}}{{v}_{g}} \qquad ( 4 )$$

φ₀(fₙ) is the phase of the frequency carrier fₙ of the generated reference signal. l₀ corresponds to the distance covered by the signal between generation thereof by the generator GEN and injection thereof into the line L by the coupler CPL. This distance corresponds notably to the travel of the signal through the digital-to-analog converter DAC.

Likewise, h corresponds to the distance covered by the signal between acquisition thereof at the coupler CPL and processing thereof by the frequency transform block FFT. This distance corresponds notably to the travel of the signal through the analog-to-digital converter ADC.

To be able to accurately measure the phase term

$$2 π {f}_{n} \frac{{l}_{0} + {l}_{1}}{{v}_{g}}$$

that is added to the phase φ₀(fₙ) of the generated signal, a calibration phase is executed, which consists in disconnecting the transmission line from the coupler CPL. In this case, the generated signal transmitted to the coupler CPL is measured directly and then processed by the spectral conversion module FFT and phase calculation module PHY. The reference phase φ_{ref}(fₙ) is measured for each frequency carrier of the signal by the module PHY. It contains the phase of the generated signal plus the phase term

$$2 π {f}_{n} \frac{{l}_{0} + {l}_{1}}{{v}_{g}}$$

resulting from the propagation of the signal through the successive equipment DAC, CPL, ADC. The result of the phase calculation performed by the module PHY is saved in a memory MEM so as to be used in the operational phase described in FIG. 5b.

In this second phase, the processing operations are identical to those described for the first embodiment of the invention, except that the reference phase is not calculated using a second phase calculation module PHY₂ applied to the reference signal, but read directly from the memory MEM.

The other processing operations performed during the operational phase are identical to those described in FIG. 4.

The second variant implementation of the invention makes it possible to further improve the accuracy with regard to the measurement of the phase of the back-propagated signal and therefore the calculation of the position of a possible fault.

The system according to any one of the variant implementations of the invention may be implemented by an electronic board on which the various components are arranged. The board may be connected to the cable to be analyzed by way of a coupling means CPL, which may be a capacitive-effect or inductive-effect directional coupler or else a resistive connection. The coupling device may be formed by physical connectors that link the signal generator to the cable or by contactless means, for example using a metal cylinder whose inner diameter is substantially equal to the outer diameter of the cable and that produces a capacitive coupling effect with the cable.

Furthermore, a processing unit, which is a computer, personal digital assistant or other equivalent electronic or computing device, may be used to drive the system according to the invention and display the results of the calculations that are performed by the component CAL on a human-machine interface, in particular the information about the detection and location of faults on the cable.

The method according to the invention, in particular the digital processing modules FFT, PHY or PHY₁ may be implemented in an embedded or non-embedded processor or in a specific device. The processor may be a generic processor, a specific processor, an application-specific integrated circuit (ASIC) or a field-programmable gate array (FPGA). The device according to the invention may use one or more dedicated electronic circuits or a general-purpose circuit. The technique of the invention may be carried out on a reprogrammable calculation machine (a processor or a microcontroller for example) executing a program comprising a sequence of instructions, or on a dedicated calculation machine (for example a set of logic gates such as an FPGA or an ASIC, or any other hardware module).

The method according to the invention may also be implemented exclusively as a computer program, the method then being applied to a signal measurement previously acquired using a measurement device. In such a case, the invention may be implemented as a computer program comprising instructions for the execution thereof. The computer program may be recorded on a recording medium that is able to be read by a processor.

The reference to a computer program that, when it is executed, performs any one of the previously described functions is not limited to an application program running on a single host computer. On the contrary, the terms computer program and software are used here in a general sense to refer to any type of computer code (for example, application software, firmware, microcode, or any other form of computer instruction) that may be used to program one or more processors so as to implement aspects of the techniques described here. The computing means or resources may notably be distributed (“cloud computing”), possibly using peer-to-peer technologies. The software code may be executed on any suitable processor (for example a microprocessor) or processor core or a set of processors, whether they are provided in a single computing device or distributed between several computing devices (for example such as possibly accessible in the environment of the device). The executable code of each program allowing the programmable device to implement the processes according to the invention may be stored for example in the hard disk or in read-only memory. Generally speaking, the program or programs may be loaded into one of the storage means of the device before being executed. The central unit is able to command and direct the execution of the instructions or software code portions of the program or programs according to the invention, which instructions are stored in the hard disk or in the read-only memory or else in the other abovementioned storage elements.

1. A method for detecting a fault in a transmission line, comprising the steps of:
acquiring, at a point of the line, using a measurement device, a temporal measurement of a reference signal previously injected into the line using an injection device, reflected off a singularity of the line and propagated back to said point,
converting the temporal measurement of the signal into the frequency domain,
measuring the phase of at least one frequency component of the signal,
subtracting a reference phase from each measured phase in order to obtain a corrected phase,
determining the distance l_{d} between said point of the line and the singularity from at least one corrected phase.

2. The method for detecting a fault of claim 1, wherein the distance l_{d} between said point of the line and the singularity is determined from a theoretical relationship expressing the phase as a function of the frequency, of the distance l_{d} and of the propagation speed of the signal in the transmission line.

3. The method for detecting a fault of claim 1, comprising the additional step of determining whether the identified singularity is a fault, at least from the determined distance l_{d} and from the length of the transmission line.

4. The method for detecting a fault of claim 1, wherein the reference phase is a cumulative phase and measuring the phase of at least one frequency component comprises, for each frequency component, determining the phase modulo π and then determining the cumulative phase.

5. The method for detecting a fault of claim 1, wherein, for each frequency component of the signal,
the reference phase is equal to the phase of the same frequency component in the previously injected reference signal.

6. The method for detecting a fault of claim 1, wherein the reference phase is determined in a preliminary calibration phase comprising:
directly connecting the injection device to the measurement device,
injecting said reference signal,
temporally measuring the propagated reference signal,
frequency-converting the temporal measurement,
for each frequency component of the signal, measuring the phase of this component, the reference phase being equal to this measurement.

7. The method for detecting a fault of claim 6, comprising said preliminary calibration phase.

8. The method for detecting a fault of claim 1, furthermore comprising an interpolation step applied to a plurality of corrected phase values corresponding to a plurality of different frequency components.

9. The method for detecting a fault claim 1, wherein the temporal measurement of the signal is converted into the frequency domain by applying a Fourier transform to the signal.

10. The method for detecting a fault of claim 1, wherein the reference signal is a multi-carrier signal, a frequency component of the signal being a frequency subcarrier of the multi-carrier signal.

11. The method for detecting a fault of claim 1, comprising a preliminary step of injecting the reference signal into the transmission line at an injection point.

12. A system for detecting a fault in a transmission line comprising a measurement device able to acquire, at a point of the line, a temporal measurement of a reference signal previously injected into the line, reflected off a singularity of the line and propagated back to said point and:
a spectral conversion unit for converting the temporal measurement of the signal into the frequency domain,
a phase measurement device for measuring the phase of at least one frequency carrier of the signal,
a subtractor for subtracting a reference phase from each measured phase in order to obtain a corrected phase,
a calculation unit for determining the distance l_{d} between said point of the line and the singularity from at least one corrected phase.

13. The system for detecting a fault claim 12, wherein the calculation unit is configured so as to determine whether the identified singularity is a fault at least from the determined distance l_{d} and from the length of the transmission line.

14. The system for detecting a fault of claim 12, comprising a display interface for displaying information characteristic of the presence of a fault on the transmission line and/or of the location of the fault.

15. The system for detecting a fault of claim 12, comprising an injection device able to inject the reference signal into the transmission line.

16. A computer program comprising instructions stored on a tangible non-transitory storage medium for executing on a processor a method for detecting a fault in a transmission line, comprising the steps of:
acquiring, at a point of the line, using a measurement device, a temporal measurement of a reference signal previously injected into the line using an injection device, reflected off a singularity of the line and propagated back to said point,
converting the temporal measurement of the signal into the frequency domain,
measuring the phase of at least one frequency component of the signal,
subtracting a reference phase from each measured phase in order to obtain a corrected phase,
determining the distance l_{d} between said point of the line and the singularity from at least one corrected phase.

17. A tangible non-transitory processor-readable recording medium on which is recorded a program comprising instructions for executing
a method for detecting a fault in a transmission line, comprising the steps of:
acquiring, at a point of the line, using a measurement device, a temporal measurement of a reference signal previously injected into the line using an injection device, reflected off a singularity of the line and propagated back to said point,
converting the temporal measurement of the signal into the frequency domain,
measuring the phase of at least one frequency component of the signal,
subtracting a reference phase from each measured phase in order to obtain a corrected phase,
determining the distance l_{d} between said point of the line and the singularity from at least one corrected phase.
